(19) United States
(12) Patent Application Publication
(10) Pub. No.: US 2025/0221317 A1
(43) Pub. Date: Jul. 3, 2025

(54) MRAM DEVICE HAVING TWO-TERMINAL SELECTORS

(71) Applicant: TAIWAN SEMICONDUCTOR MANUFACTURING COMPANY, LTD., Hsinchu (TW)

(72) Inventors: Elia AMBROSI, Hsinchu (TW); MingYuan SONG, Hsinchu (TW); Cheng-Hsien WU, Hsinchu (TW); Xinyu BAO, Hsinchu (TW)

(21) Appl. No.: 18/625,485

(22) Filed: Apr. 3, 2024

Related U.S. Application Data
(60) Provisional application No. 63/615,453, filed on Dec. 28, 2023.

(51) Int. Cl. H10N 50/10; G11C 5/06; H10B 61/00; H10N 50/01

(52) U.S. Cl. CPC H10N 50/10; G11C 5/063; H10B 61/10; H10N 50/01

(57) ABSTRACT

A memory device includes a spin-orbit torque (“SOT”) conductor, a magnetic tunneling junction (“MTJ”) structure above the SOT conductor, a two-terminal read selector above the MTJ structure, a two-terminal write selector above the MTJ structure, and a bit line below the SOT conductor. The two-terminal read selector is conductively connected to the pinned layer in the MTJ structure. The two-terminal write selector is conductively connected to a first terminal of the SOT conductor. The bit line is conductively connected to a second terminal of the SOT conductor.

### CROSS-REFERENCE TO RELATED APPLICATIONS

This application claims the benefit of U.S. Provisional Application No. 63/615,453, filed Dec. 28, 2023, which is hereby incorporated by reference in its entirety.

### BACKGROUND

MRAM (“Magnetoresistive Random Access Memory”) is a type of non-volatile memory technology that uses magnetic states to store information. In MRAM, information is stored by manipulating the magnetic orientation of ferromagnetic material. The basic structure of a MRAM cell includes a magnetic tunnel junction, which includes two ferromagnetic layers separated by a tunnel barrier layer. The resistance of the magnetic tunnel junction depends upon the relative alignment of the magnetization of the two ferromagnetic layers. In Spin-Orbit Torque MRAM (“SOT-MRAM”), a conductive layer is deposited near the magnetic tunnel junction in a memory cell, and the flow of an electric current through the conductive layer generates a spin-orbit torque which is used to manipulate a magnetic state of the magnetic tunnel junction of the memory cell.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a three-dimensional view of a SOT-MRAM device having a two-terminal write selector and a two-terminal read selector, in accordance with some embodiments.

FIG. 1B is a schematic view of the SOT-MRAM device of FIG. 1A, in accordance with some embodiments.

FIG. 1C is a layout view of an integrated circuit having a matrix of SOT-MRAM devices each implemented as the device of FIG. 1A, in accordance with some embodiments.

FIG. 2A is a three-dimensional view of a SOT-MRAM device having a two-terminal write selector and a two-terminal read selector, in accordance with some embodiments.

FIG. 2B is a schematic view of the SOT-MRAM device of FIG. 2A, in accordance with some embodiments.

FIG. 2C is a layout view of an integrated circuit having a matrix of SOT-MRAM devices each implemented as the device of FIG. 2A, in accordance with some embodiments.

FIG. 3 and FIGS. 4A-4B are circuit diagrams of integrated circuits each having a matrix of SOT-MRAM devices, in accordance with some embodiments.

FIG. 5 is a circuit diagram of an integrated circuit having a matrix of SOT-MRAM devices configured to perform a matrix operation on a vector, in accordance with some embodiments.

FIGS. 6A-6H are cross-sectional views of various device structures formed during a process of fabricating the SOT-MRAM device of FIG. 2A, in accordance with some embodiments.

FIG. 7A is a flowchart of a method of fabricating a memory device, in accordance with some embodiments.

FIG. 7B is a flowchart of a method of fabricating a memory device, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a SOT-MRAM device of a memory device includes a spin-orbit torque (“SOT”) conductor, a magnetic tunneling junction (“MTJ”) structure arranged above the SOT conductor, a two-terminal read selector arranged above the MTJ structure, and a two-terminal write selector. A read word line above the SOT conductor is conductively connected to the MTJ structure through the two-terminal read selector. A write word line, which is either above the SOT conductor or below the SOT conductor, is conductively connected to a first terminal of the SOT conductor though the two-terminal write selector. A bit line below the SOT conductor is conductively connected to a second terminal of the SOT conductor.

In some embodiments, the two-terminal write selector is above the MTJ structure. In some embodiments, each of the two-terminal read selector and the two-terminal write selector has a switching layer fabricated from a same layer of switching material above the MTJ structure. In an implementation in which both the two-terminal read selector and the two-terminal write selector are above the MTJ structure, the SOT-MRAM device has reduced number of stacked conductive layers measured from the bit line below the SOT conductor to the read word line above the SOT conductor, as compared with some other alternative implementations. Reducing the number of stacked conductive layers in a single SOT-MRAM device improves the efficiency of stacking more SOT-MRAM devices on top of each other above a substrate. Consequently, more layers of SOT-MRAM devices are deposited above a substrate, given a same thickness limitation for the total stack height of SOT-MRAM devices.

In some embodiments, the two-terminal write selector is below the MTJ structure but above the bit line, which enables the SOT conductor and the bit line vertically stacked with each other above a substrate. Stacking vertically the SOT conductor and the bit line with each other reduces the memory cell area occupied by the SOT-MRAM device, thereby memory densities of a single layer of SOT-MRAM devices are improved.

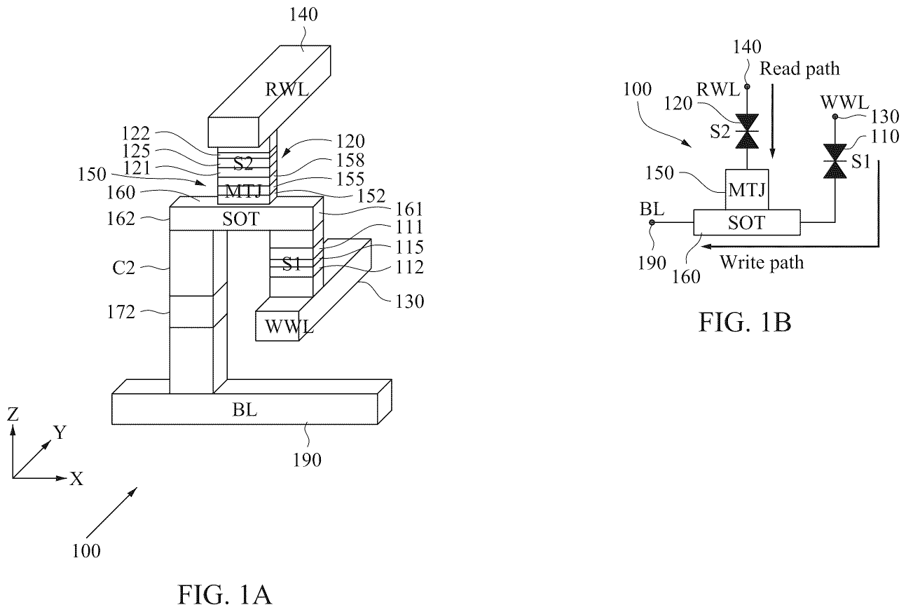

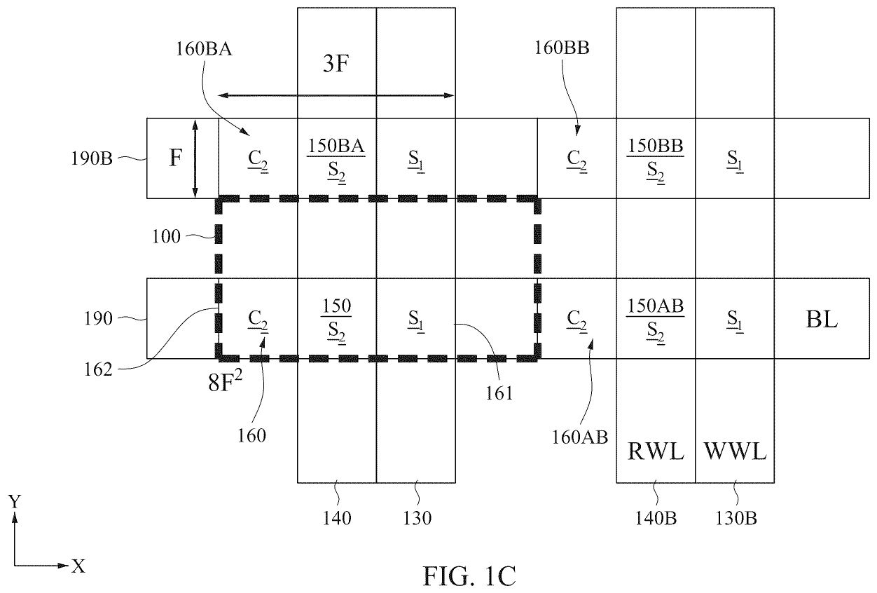

FIG. 1A is a three-dimensional view of a SOT-MRAM device 100 having a two-terminal write selector and a two-terminal read selector, in accordance with some embodiments. The SOT-MRAM device 100 is a memory device that uses magnetic states to store information. In FIG. 1A, the SOT-MRAM device 100 includes a magnetic tunneling junction structure (“MTJ structure”) 150, a spin-orbit torque conductor (“SOT conductor”) 160, a two-terminal write selector 110, and a two-terminal read selector 120. The two-terminal write selector 110 and the two-terminal read selector 120 are correspondingly labeled as selector S1 and selector S2. The MTJ structure 150 is arranged above the SOT conductor 160.

In FIG. 1A, the MTJ structure 150 has a free layer 152, a pinned layer 158, and a tunnel barrier layer 155. The tunnel barrier layer 155 is sandwiched between the free layer 152 and the pinned layer 158. Each of the free layer 152 and the pinned layer 158 is a conductive layer made of ferromagnetic materials, but the tunnel barrier layer 155 is a thin insulating layer made of high electrical resistance materials. The thickness of the tunnel barrier layer 155 is sufficiently thin to enable electrons quantum mechanically tunneling through the thin insulating layer between the two ferromagnetic layers. The probability of tunneling is influenced by the relative alignment of the magnetic moments of the two ferromagnetic layers.

While the magnetic moments of the pinned layer 158 are typically fixed in orientation, the magnetic moments of the free layer 152 are manipulated with an external magnetic field, with an applied current, or with other means. When the magnetic moments of the free layer 152 are parallel to the magnetic moments of the pinned layer 158, the tunneling probability is higher, resulting in lower electrical resistance. Conversely, when the magnetic moments of the free layer 152 are antiparallel to the magnetic moments of the pinned layer 158, the tunneling probability decreases, leading to higher electrical resistance. The two different values of the electrical resistance based on the relative orientation of the magnetic moments of the two ferromagnetic layers is exploited to represent the binary information Zero (“0”) and the binary information One (“1”) in the MRAM cell.

In FIG. 1A, the magnetic moments of the free layer 152 are manipulated with an electric current passing though the SOT conductor 160 which is deposited in proximity of the free layer 152. The free layer 152 is also in conductive contact with the SOT conductor 160. When an electric current flows through the SOT conductor 160, the spin-orbit torque effect induces a flow of electron spins within the SOT conductor 160. The spin-orbit torque generated by the spin current exerts a torque on the magnetic moments of the free layer 152 in the MTJ structure 150. The magnetic moments in the free layer 152 can be reoriented or flipped in magnetization direction by the spin-orbit torque, under a condition that the spin-orbit torque becomes sufficiently strong. A sufficiently large electric current passing though the SOT conductor 160 determines the orientation of the magnetic moments in the free layer 152. Because the resistance of the magnetic tunnel junction depends upon the orientation of the magnetic moments in the free layer 152, a write current applied to the SOT conductor 160 provides the mechanism to set the resistance of the magnetic tunnel junction, whereby the binary information is written into the MRAM cell.

In FIG. 1A, a write current is applied to one of the terminals of the SOT conductor 160 through the two-terminal write selector 110. The value of the resistance of the magnetic tunnel junction is detected based on the value of a current that serially passes through the two-terminal read selector 120 and the MTJ structure 150 to the SOT conductor 160.

The two-terminal write selector 110 is arranged below both the MTJ structure 150 and the SOT conductor 160, while the two-terminal read selector 120 is arranged above the MTJ structure 150. Each of the two-terminal write selector 110 and the two-terminal read selector 120 includes a switching layer sandwiched between two conductor layers. In the two-terminal write selector 110, a switching layer 115 is sandwiched between two conductor layers 111 and 112. The conductor layer 111 is conductively connected to a first terminal of the SOT conductor 160 (which is the terminal neighboring to a first edge 161 of the SOT conductor 160) through a vertical conductor C1. In the two-terminal read selector 120, a switching layer 125 is sandwiched between two conductor layers 121 and 122. The conductor layer 121 is conductively connected to the pinned layer 158 in the MTJ structure 150.

Each of the two-terminal write selector 110 and the two-terminal read selector 120 is a two-terminal device (e.g., a non-linear diode) that has highly non-linear current-voltage characteristics, such as a non-linear diode. As long as the voltage applied to the two-terminal device is much smaller than a threshold voltage, the current leaks through the two-terminal device can be negligently small. On the other hand, once the voltage applied to the two-terminal device becomes larger than a threshold voltage, the current passing through the two-terminal device can increase rapidly with an increase of the applied voltage. The two-terminal device is practically set to a non-conducting state when a first voltage smaller than the threshold voltage is applied to the two-terminal device, and the two-terminal device is practically set to a conducting state when a second voltage larger than the threshold voltage is applied to the two-terminal device. The first voltage is selected to raise the off-resistance Roff of the two-terminal device when the device is at the non-conducting state, and the second voltage is selected to lower the on-resistance Ron of the two-terminal device when the device is at the conducting state. It is generally better to have a two-terminal device that has a large off-to-on ratio Roff/Ron (i.e., the ratio between the off-resistance Roff and the on-resistance Ron). The non-linearity of the two-terminal device often depends upon the switching layer sandwiched between the two conductor layers in the two-terminal device.

In some embodiments, the switching layer 115 in the two-terminal write selector 110 includes a chalcogenide material, a solid-electrolyte material, a phase-change material, or an oxide insulating material. In some embodiments, the switching layer 125 in the two-terminal read selector 120 also includes a chalcogenide material, a solid-electrolyte material, a phase-change material, or an oxide insulating material. In some embodiments, each of the two-terminal write selector 110 and the two-terminal read selector 120 is a bi-directional diode. In some embodiments, while the two-terminal write selector 110 is a bi-directional diode, the two-terminal read selector 120 is a uni-directional diode.

The SOT-MRAM device 100 of FIG. 1A also includes a bit line 190 extending in the X-direction, a write word line 130 extending in the Y-direction, and a read word line 140 extending in the Y-direction. Here, the Y-direction is perpendicular to the X-direction. The read word line 140 is fabricated in a conducting layer above the two-terminal read selector 120. The write word line 130 is fabricated in a conducting layer below the two-terminal write selector 110. The bit line 190 is fabricated in a conducting layer below the write word line 130.

The bit line 190 is conductively connected to a second terminal of the SOT conductor 160 (which is the terminal neighboring to a second edge 162 of the SOT conductor 160) though a vertical conductor C2. In some implementations, the vertical conductor C2 includes a conductor segment 172 which is in the same conducting layer as the write word line 130. The vertical conductor C2 also includes one or more vias connectors for the connecting conductor segment 172 to the SOT conductor 160 and for connecting the conductor segment 172 to the bit line 190. The write word line 130 is conductively connected to the conductor layer 112 of the two-terminal write selector 110 (which is also labeled as selector S1). The read word line 140 is conductively connected to the conductor layer 122 of the two-terminal read selector 120 (which is also labeled as selector S2). In FIG. 1A, the two-terminal write selector 110 is electrically coupled between the write word line 130 and the first terminal of the SOT conductor 160, while the two-terminal read selector 120 is electrically coupled between the read word line 140 and the MTJ structure 150.

FIG. 1B is a schematic view of the SOT-MRAM device of FIG. 1A, in accordance with some embodiments. The write operation and the read operation on the SOT-MRAM device of FIG. 1A is described with reference to FIG. 1B.

During the write operation, the read word line 140 is set at a read off voltage V_{read-off}, which sets the two-terminal read selector 120 at the non-conducting state, and consequently the leakage current passing though the two-terminal read selector 120 and the MTJ structure 150 becomes practically negligible. In some alternative implementations, the read word line 140 is set to a float voltage, which keeps the two-terminal read selector 120 at the non-conducting state.

During the write operation, a bit voltage V_{B} is applied to the bit line 190. In some embodiments, the bit voltage V_{B} is either set to a negative voltage −|V⁻| or set to a positive voltage |V⁺|. The bit voltage V_{B} is set to the negative voltage −|V⁻| for writing a first binary value (such as the value “1”) into the SOT-MRAM device 100. The bit voltage V_{B} is set to the positive voltage |V⁺| for writing a second binary value (such as the value “0”) into the SOT-MRAM device 100. In some alternative embodiments, the bit voltage V_{B} is set to one of three voltage values: a negative voltage −|V⁻|, a positive voltage |V⁺|, and a null voltage |V⁰| (which typically is the zero voltage, |V⁰|=0).

The write operation on multiple SOT-MRAM devices connected to a same write word line is typically performed during a writing time period which is further divided into a positive-current writing time period and a negative-current writing time period. The write operation on SOT-MRAM devices for receiving a first binary value (such as the value “1”) is performed during the positive-current writing time period. The write operation on SOT-MRAM devices for receiving a second binary value (such as the value “0”) is performed during the negative-current writing time period.

During the positive-current writing time period, a positive selecting voltage |V⁺ₒₙ| is applied to the write word line 130. The voltage difference between the write word line 130 and the bit line 190 is |V⁺ₒₙ|−V_{B}, which depends upon the bit voltage V_{B} applied to the bit line 190.

If the bit voltage V_{B} at the bit line 190 is the negative voltage −|V⁻|, the voltage difference between is the write word line 130 and the bit line 190 becomes |V⁺ₒₙ|+|V⁻|. The forward bias voltage |V⁺ₒₙ|+|V⁻| is sufficiently large to set the two-terminal write selector 110 to the conducting state, which causes a positive current flow into the SOT conductor 160 from the write word line 130 to the bit line 190. The positive current flow in the SOT conductor 160 sets the magnetic moments in the free layer 152 to a first orientation, whereby a first binary value (such as the value “1”) is written into the SOT-MRAM device 100.

If the bit voltage V_{B} at the bit line 190 is the positive voltage |V⁺|, the voltage difference between the write word line 130 and the bit line 190 becomes |V⁺ₒₙ|−|V⁺|. The forward bias voltage |V⁺ₒₙ|−|V⁺| is not large enough to set the two-terminal write selector 110 into the conducting state. Consequently, no current passes though the SOT conductor 160 from the write word line 130 to the bit line 190, and the magnetic moments in the free layer 152 of the SOT-MRAM device 100 remains unchanged.

If the bit voltage V_{B} at the bit line 190 is the null voltage |V⁰| (e.g., |V⁰|=0), the voltage difference between the write word line 130 and the bit line 190 becomes |V⁺ₒₙ|−|V⁰|. The forward bias voltage |V⁺ₒₙ|−|V⁰| is insufficient to drive the two-terminal write selector 110 into the conducting state. Consequently, no current passes though the SOT conductor 160 from the write word line 130 to the bit line 190, and the magnetic moments in the free layer 152 of the SOT-MRAM device 100 remains unchanged. In an example embodiment with |V⁰|=0, if the voltage |V⁺ₒₙ| is smaller than the threshold voltage of the two-terminal write selector 110, then, the voltage difference |V⁺ₒₙ|−|V⁰| (between the write word line 130 and the bit line 190) is still smaller than the threshold voltage of the two-terminal write selector 110.

During the negative-current writing time period, a negative selecting voltage-|V⁻ₒₙ| is applied to the write word line 130. The voltage difference between the write word line 130 and the bit line 190 is −|V⁻ₒₙ|−V_{B}, which depends upon the bit voltage V_{B} applied to the bit line 190.

If the bit voltage V_{B} at the bit line 190 is the negative voltage −|V⁻|, the voltage difference between the write word line 130 and the bit line 190 becomes −|V⁻ₒₙ|+|V⁻|, where |V⁻ₒₙ|>|V⁻|. The reverse bias voltage |V⁻ₒₙ|−|V⁻| is not large enough to set the two-terminal write selector 110 into the conducting state. Consequently, no current passes though the SOT conductor 160 from the write word line 130 to the bit line 190, and the magnetic moments in the free layer 152 of the SOT-MRAM device 100 remains unchanged.

If the bit voltage V_{B} at the bit line 190 is the positive voltage |V⁺|, the voltage difference between is the write word line 130 and the bit line 190 becomes −|V⁻ₒₙ|−|V⁺|. The reverse bias voltage |V⁻ₒₙ|+|V⁺| is sufficiently large to set the two-terminal write selector 110 to the conducting state under reverse bias, which causes a negative current flow into the SOT conductor 160 from the write word line 130 to the bit line 190 (that is, a positive current flowing from the bit line 190 to the write word line 130). The negative current flow in the SOT conductor 160 sets the magnetic moments in the free layer 152 to a second orientation, whereby a second binary value (such as the value “0”) is written into the SOT-MRAM device 100.

If the bit voltage V_{B} at the bit line 190 is the null voltage |V⁰| (e.g., |V⁰|=0), the voltage difference between the write word line 130 and the bit line 190 becomes −|V⁻ₒₙ|−|V⁰|. The reverse bias voltage |V⁻ₒₙ|+|V⁰| is insufficient to drive the two-terminal write selector 110 into the conducting state. Consequently, no current passes though the SOT conductor 160 from the write word line 130 to the bit line 190, and the magnetic moments in the free layer 152 of the SOT-MRAM device 100 remains unchanged. In an example embodiment with |V⁰|=0, if the voltage |V⁻ₒₙ| is smaller than the threshold voltage of the two-terminal write selector 110, then, the reverse bias voltage |V⁻ₒₙ|+|V⁰| applied to the two-terminal write selector 110 is still smaller than the threshold voltage of the two-terminal write selector 110.

Additionally, because the bit line 190 is typically connected to multiple SOT-MRAM devices in a matrix of SOT-MRAM devices, when a SOT-MRAM device 100 connected to the bit line 190 is selected for writing operation, other SOT-MRAM devices connected to the same bit line (i.e. 190) are typically unselected for writing operation.

During the write operation, while the bit voltage V_{B} is applied to the bit line 190, in order to unselect another SOT-MRAM device which is also connected to the same bit line (i.e. 190), a word unselect voltage V_{off} is applied to a corresponding write word line connected to the unselected SOT-MRAM device. The voltage difference |V_{off}−V_{B}| is set at a value to keep the two-terminal write selector 110 in each of the unselect SOT-MRAM devices at the non-conducting state.

During the read operation, the write word line 130 is set at a write off voltage V_{wrtie-off}, which sets the two-terminal write selector 110 at the non-conducting state, and consequently the leakage current passing though the two-terminal write selector 110 and the SOT conductor 160 becomes practically negligible. In some alternative implementations, the write word line 130 is set to a float voltage, which keeps the two-terminal write selector 110 at the non-conducting state.

During the read operation, to select a SOT-MRAM device 100 for reading, a word read voltage V^{R}ₒₙ is applied to the read word line 140 to drive the two-terminal read selector 120 into the conducting state. The word read voltage V^{R}ₒₙ is chosen with a value to make the voltage difference |V^{R}ₒₙ−V_{RB}| significantly larger than the threshold voltage of the two-terminal read selector 120, where the voltage V_{RB} is the voltage at the bit line 190. In some embodiments, the bit line 190 is connected to a sense amplifier SA, and the voltage V_{RB} is the voltage across a bit capacitor coupled between the bit line 190 and a common ground. The change rate of the voltage V_{RB} over time is proportional to the current passing through the MTJ structure 150. In some alternative embodiments, the bit line 190 is connected to one of the differential inputs of a current-to-voltage converter, and the voltage V_{RB} at the bit line 190 is maintained at a virtual common voltage V_{G} by the current-to-voltage converter.

When the SOT-MRAM device 100 is selected for reading, the current flowing from the read word line 140 to the bit line 190 is the current that passes through the two-terminal read selector 120 and the MTJ structure 150. The current flowing from the read word line 140 to the bit line 190 is inversely proportional to the resistance of the magnetic tunnel junction. Once the current flowing from the read word line 140 to the bit line 190 is detected, the binary information stored in the MRAM cell is read out.

Because the bit line 190 is typically connected to multiple SOT-MRAM devices in a matrix of SOT-MRAM devices, when a SOT-MRAM device 100 connected to the bit line 190 is selected for reading operation, other SOT-MRAM devices connected to the same bit line (i.e. 190) are typically unselected for reading operation. During the read operation, in order to unselect another SOT-MRAM device which is also connected to the same bit line (i.e. 190), a word unselect voltage V^{R}_{off} is applied to a corresponding read word line connected to the unselected SOT-MRAM device. The voltage difference |V^{R}_{off}−V_{RB}| is set at a value to keep the two-terminal read selector 120 in each of the unselect SOT-MRAM devices at the non-conducting state, where the voltage V_{RB} is the voltage at the bit line 190. In some embodiments, the bit line 190 is connected to a current-to-voltage converter which keeps the voltage on the bit line 190 at a virtual common voltage V_{G}, the voltage difference |V^{R}_{off}−V_{G}| is set at a value to keep the two-terminal read selector 120 in each of the unselect SOT-MRAM devices at the non-conducting state.

FIG. 1C is a layout view of an integrated circuit having a matrix of SOT-MRAM devices each implemented as the device of FIG. 1A, in accordance with some embodiments. In the example layout of FIG. 1C, the integrated circuit includes four SOT-MRAM cells arranged in a matrix of two rows and two columns. Each of the SOT-MRAM cells in the two-by-two matrix has an SOT-MRAM device which is implemented with the same device structure as the device in FIG. 1A.

In FIG. 1C, the integrated circuit includes bit lines 190 and 190B extending in the X-direction, write word lines 130 and 130B extending in the Y-direction, and read word lines 140 and 140B extending in the Y-direction. Each of the four SOT-MRAM cells in the two-by-two matrix has a corresponding MTJ structure deposited at the intersection area between one of the bit lines and one of the read word lines. Specifically, the MTJ structure 150 in the SOT-MRAM cell at the first row and the first column is deposited at the intersection area between the bit line 190 and the read word line 140. The MTJ structure 150AB in the SOT-MRAM cell at the first row and the second column is deposited at the intersection area between the bit line 190 and the read word line 140B. The MTJ structure 150BA in the SOT-MRAM cell at the second row and the first column is deposited at the intersection area between the bit line 190B and the read word line 140. The MTJ structure 150BB in the SOT-MRAM cell at the second row and the second column is deposited at the intersection area between the bit line 190B and the read word line 140B.

In FIG. 1C, the read word lines 140 and 140B are in a conductive layer above the MTJ structures. The MTJ structure in each of the SOT-MRAM cells is electrically connected to one of the read word lines through a corresponding two-terminal read selector above the MTJ structure. For example, the MTJ structures 150 and 150BA are electrically connected to the read word line 140 correspondingly through a two-terminal read selector S2 above the MTJ structure 150 and a two-terminal read selector S2 above the MTJ structure 150BA. The MTJ structures 150AB and 150BB are electrically connected to the read word line 140B correspondingly through a two-terminal read selector S2 above the MTJ structure 150AB and a two-terminal read selector S2 above the MTJ structure 150BB.

In FIG. 1C, each of the four SOT-MRAM cells has a corresponding SOT conductor deposited underneath the MTJ structure in the SOT-MRAM cell. For example, in the SOT-MRAM cell at the first row and the first column of the matrix, the SOT conductor 160 is arranged below the MTJ structure 150. In the SOT-MRAM cell at the first row and the second column, the SOT conductor 160AB is arranged below the MTJ structure 150AB. In the SOT-MRAM cell at the second row and the first column, the SOT conductor 160BA is arranged below the MTJ structure 150BA. In the SOT-MRAM cell at the second row and the second column, the SOT conductor 160BB is arranged below the MTJ structure 150BB.

In FIG. 1C, the write word lines 130 and 130B are in a conductive layer below the SOT conductors. The first terminal of the SOT conductor in each of the SOT-MRAM cells is electrically connected to one of the write word lines through a corresponding two-terminal write selector below the SOT conductor. For example, the first terminal of the SOT conductors 160 and 160BA is electrically connected to the write word line 130B correspondingly through a two-terminal write selector S1 below the SOT conductor 160 and a two-terminal write selector S1 below the SOT conductor 160BA. The first terminal of the SOT conductors 160AB and 160BB is electrically connected to the write word line 130B correspondingly through a two-terminal write selector S1 below the SOT conductor 160AB and a two-terminal write selector S1 below the SOT conductor 160BB.

In FIG. 1C, the bit lines 190 and 190B are in a conductive layer below the write word lines 130 and 130B, while the write word lines 130 and 130B are below the SOT conductors. The second terminal of the SOT conductor in each of the SOT-MRAM cells is electrically connected to one of the bit lines through a corresponding vertical conductor below the SOT conductor. For example, the second terminal of the SOT conductors 160 and 160AB is electrically connected to the bit line 190 correspondingly through a vertical conductor C2 below the SOT conductor 160 and a vertical conductor C2 below the SOT conductor 160AB. The second terminal of the SOT conductors 160BA and 160BB is electrically connected to the bit line 190B correspondingly through a vertical conductor C2 below the SOT conductor 160BA and a vertical conductor C2 below the SOT conductor 160BB.

In FIG. 1C, each of the SOT conductors 160 and 160AB above the bit line 190 is vertically stacked with the bit line 190, and each of the SOT conductors 160BA and 160BB above the bit line 190B is vertically stacked with the bit line 190B. Each of the bit lines 190 and 190B has a line width which is equal to one F unit, and the bit lines 190 and 190B are separated by a pitch distance which is equal to one F unit. Thus, the SOT-MRAM device in FIG. 1C has a cell height (along the Y-direction) of two F units (“2F”). Here, the F unit is a unit used to measure the dimensions of various elements in a layout diagram. In FIG. 1C, the SOT conductor in each SOT-MRAM device has a length of 3 F. For example, the length measured from the first edge 161 of the SOT conductor 160 to the second edge 162 of the SOT conductor 160 is equal to three F units (“3F”). The SOT conductors in two adjacent SOT-MRAM cells are separated along the X-direction with a gap of one F unit. Thus, the SOT-MRAM device in FIG. 1C has a cell length (along the X-direction) of four F units (“4F”). The cell area of each SOT-MRAM device in FIG. 1C is 8F².

In FIG. 1C, because the SOT conductor in a SOT-MRAM device is vertically stacked with the bit line, as long as the width (along the Y-direction) of the SOT conductor is less than or equal to the width (along the Y-direction) of the bit line, the SOT conductor does not contribute to additional increase of the cell height, and consequently the cell height of the SOT-MRAM device in FIG. 1C is maintained at two F units. The cell area of the SOT-MRAM device in FIG. 1C is smaller than the cell area of certain SOT-MRAM device implemented with some other cell designs in which the cell height of a SOT-MRAM device is larger than two F units while the SOT conductor is not vertically stacked with the bit line.

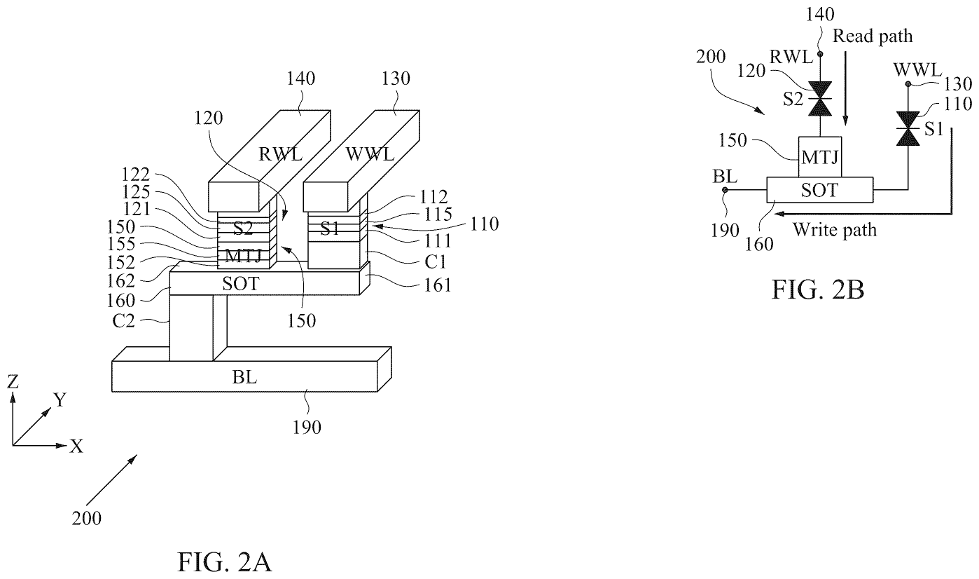

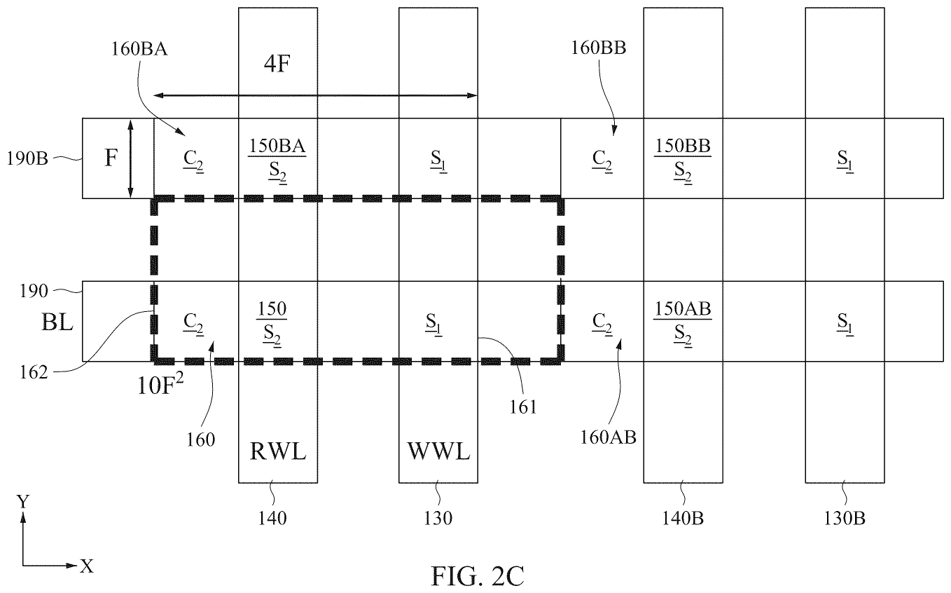

In addition to the embodiments of the SOT-MRAM devices in FIGS. 1A-1C, alternative embodiments of the SOT-MRAM devices are shown FIGS. 2A-2C.

FIG. 2A is a three-dimensional view of a SOT-MRAM device 200 having a two-terminal write selector and a two-terminal read selector, in accordance with some embodiments. The main differences between the SOT-MRAM device 100 of FIG. 1A and the SOT-MRAM device 200 of FIG. 2A are in the vertical positions of the two-terminal write selector 110 and the write word line 130 relative to the SOT conductor 160. Other differences are in the vertical position of the bit line 190 and the vertical conductor C2 associated with the bit line 190.

In the SOT-MRAM device 100 of FIG. 1A, the two-terminal write selector 110 and the write word line 130 are arranged below the SOT conductor 160, while the two-terminal read selector 120 is arranged above the SOT conductor 160. In contrast, in the SOT-MRAM device 200 of FIG. 2A, the two-terminal write selector 110 and the write word line 130 are arranged above the SOT conductor 160, while the two-terminal read selector 120 is arranged also above the SOT conductor 160.

In FIG. 2A, the write word line 130 extending in the Y-direction is fabricated in a same conducting layer as the read word line 140. The write word line 130 and the read word line 140 extending in the same direction, while parallelly positioned in a same conducting layer, are separated from each other with a gap which is typically filled with insulation materials. The two-terminal write selector 110 is arranged below the write word line 130 but above the SOT conductor 160. The two-terminal write selector 110 includes a switching layer 115 sandwiched between two conductor layers 111 and 112. The conductor layer 111 below the switching layer 115 is conductively connected to a first terminal of the SOT conductor 160 (which is the terminal neighboring to a first edge 161 of the SOT conductor 160). The conductor layer 112 above the switching layer 115 is conductively connected to the write word line 130.

In some embodiments, the switching layer 115 in the two-terminal write selector 110 and the switching layer 125 in the two-terminal read selector 120 are fabricated from a same layer of switching material (which is formed from one of a chalcogenide material, a solid-electrolyte material, a phase-change material, or an oxide insulating material). In some embodiments, the conductor layer 111 in the two-terminal write selector 110 and the conductor layer 121 in the two-terminal read selector 120 are fabricated from a same layer of conductive material. In some embodiments, the conductor layer 112 in the two-terminal write selector 110 and the conductor layer 122 in the two-terminal read selector 120 are fabricated from a same layer of conductive material.

The bit line 190 in FIG. 2A is fabricated in a conductive layer which has a shorter distance to the SOT conductor 160 than the conductive layer containing the bit line 190 of FIG. 1A, because the bit line 190 in FIG. 2A is now fabricated in the conductive layer which contains the connecting conductor segment 172 of FIG. 1A. As the connecting conductor segment 172 is removed from the vertical conductor C2 of FIG. 1A, the vertical conductor C2 in FIG. 2A is correspondingly shortened.

FIG. 2B is a schematic view of the SOT-MRAM device of FIG. 2A, in accordance with some embodiments. Despite the differences between the SOT-MRAM device 200 in FIG. 2A and the SOT-MRAM device 100 in FIG. 1A, the equivalent circuit in FIG. 2B (which represents the SOT-MRAM device 200 in FIG. 2A) is functionally identical to the equivalent circuit in FIG. 1B (which represents the SOT-MRAM device 100 in FIG. 1A). The write operation on the SOT-MRAM device 200 of FIG. 2A is the same as the write operation on the SOT-MRAM device 100 of FIG. 1A. The read operation on the SOT-MRAM device 200 of FIG. 2A is the same as the read operation on the SOT-MRAM device 100 of FIG. 1A.

FIG. 2C is a layout view of an integrated circuit having a matrix of SOT-MRAM devices each implemented as the device of FIG. 2A, in accordance with some embodiments. The differences between the layouts in FIG. 2C and the layouts in FIG. 1C include the different layout positions of the write word line relative to the read word line, the different layout positions of the two-terminal write selector relative to the MTJ structure, the different lengths of the SOT conductor, and the different cell lengths of the SOT-MRAM cell.

In FIG. 2C, the write word line 130 and the read word line 140 are separated along the X-direction by a gap of one F unit. The write word line 130B and the read word line 140B are similarly separated along the X-direction by a gap of one F unit. In FIG. 2C, the two-terminal write selector S1 at the intersection area between a write word line and a bit line is moved along the X-direction further away from the MTJ structure in the same SOT-MRAM cell, as compared with the layout in FIG. 1C. In FIG. 2C, the length of the SOT conductor is enlarged to four F units (“4F”), and the cell length of the SOT-MRAM device is enlarged to five F units (“5F”), as compared with the layout in FIG. 1C. The cell area of each SOT-MRAM device in FIG. 2C becomes 10F².

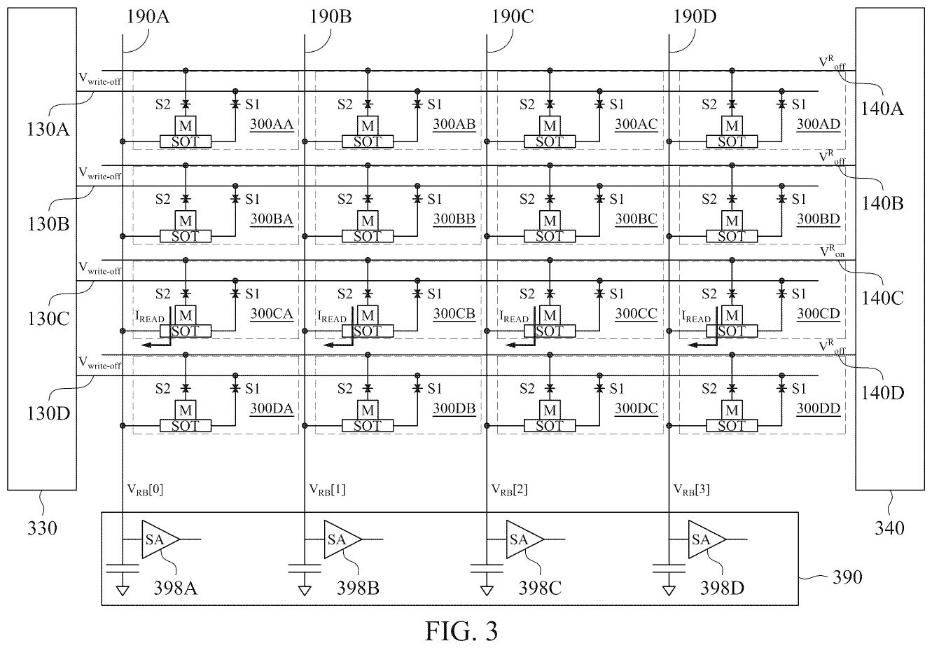

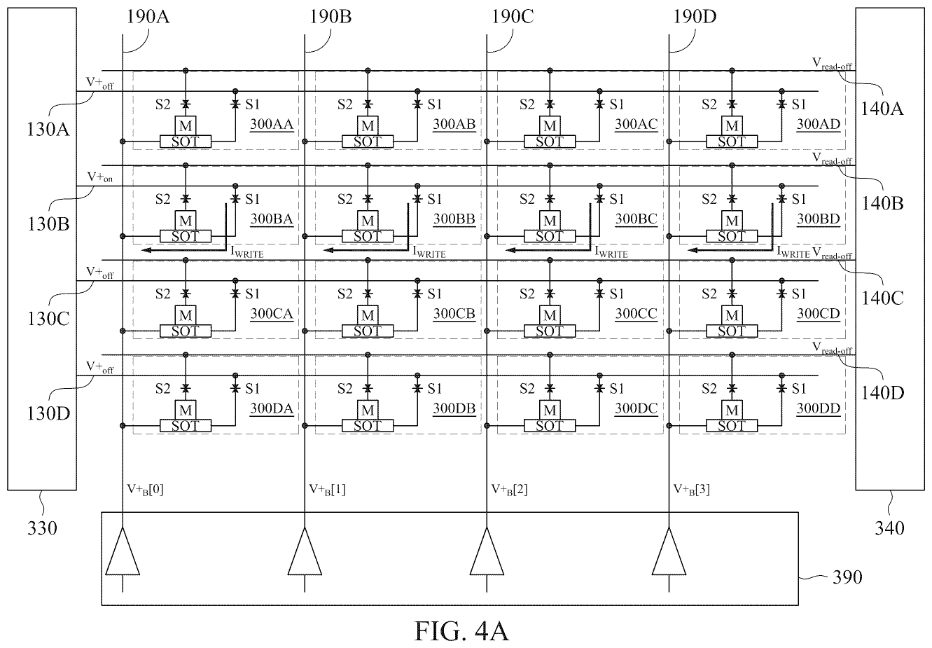

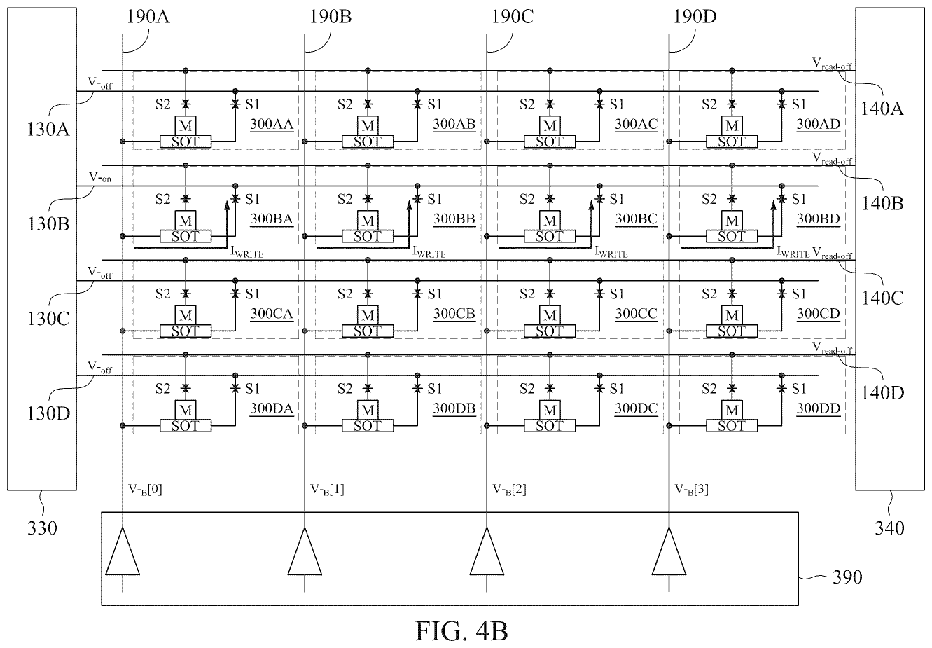

FIG. 3 and FIGS. 4A-4B are circuit diagrams of integrated circuits each having a matrix of SOT-MRAM devices, in accordance with some embodiments. In FIG. 3 and FIGS. 4A-4B, the SOT-MRAM devices are arranged in a four-by-four matrix: the first row of the matrix includes SOT-MRAM devices 300AA-300AD, the second row of the matrix includes SOT-MRAM devices 300BA-300BD, the third row of the matrix includes SOT-MRAM devices 300CA-300CD, and the fourth row of the matrix includes SOT-MRAM devices 300DA-300DD. In some embodiments, each of the SOT-MRAM devices in the matrix of SOT-MRAM devices is implemented as the SOT-MRAM device 100 of FIG. 1A. In some embodiments, each of the SOT-MRAM devices in the matrix of SOT-MRAM devices is implemented as the SOT-MRAM device 200 of FIG. 2A.

The SOT conductor in each SOT-MRAM device in the first row is connected to a write word line 130A through a two-terminal write selector S1, while the MTJ structure in each SOT-MRAM device in the first row is connected to a read word line 140A through a two-terminal read selector S2. The SOT conductor in each SOT-MRAM device in the second row is connected to a write word line 130B through a two-terminal write selector S1, while the MTJ structure in each SOT-MRAM device in the second row is connected to a read word line 140B through a two-terminal read selector S2. The SOT conductor in each SOT-MRAM device in the third row is connected to a write word line 130C through a two-terminal write selector S1, while the MTJ structure in each SOT-MRAM device in the third row is connected to a read word line 140C through a two-terminal read selector S2. The SOT conductor in each SOT-MRAM device in the fourth row is connected to a write word line 130D through a two-terminal write selector S1, while the MTJ structure in each SOT-MRAM device in the fourth row is connected to a read word line 140D through a two-terminal read selector S2. Each of the write word lines 130A-130D is connected to a write selection circuit 330. Each of the read word line 140A-140D is connected to a read selection circuit 340.

The second terminal of the SOT conductor in each of the SOT-MRAM devices 300AA-300DA in the first column is connected to a bit line 190A. The second terminal of the SOT conductor in each of the SOT-MRAM devices 300AB-300DB in the second column is connected to a bit line 190B. The second terminal of the SOT conductor in each of the SOT-MRAM devices 300AC-300DC in the third column is connected to a bit line 190C. The second terminal of the SOT conductor in each of the SOT-MRAM devices 300AD-300DD in the fourth column is connected to a bit line 190D. Each of the bit lines 190A-190D is connected to a memory input-output circuit 390.

The read operation on a matrix of SOT-MRAM devices is described with reference to FIG. 3. During the read operation, a write off voltage V_{wrtie-off} is applied to each of the write word lines 130A-130D by the write selection circuit 330. The matrix of SOT-MRAM devices in FIG. 3 is read row by row. That is, during each reading time period, one row of SOT-MRAM devices is selected for read operation. The SOT-MRAM devices 300AA-300AD in the first row, the SOT-MRAM devices 300BA-300BD in the second row, the SOT-MRAM devices 300CA-300CD in the third row, and the SOT-MRAM devices 300DA-300DD in the fourth row are correspondingly read in a first reading time period, a second reading time period, a third reading time period, and a fourth reading time period.

During each reading time period, as one row of SOT-MRAM devices is selected for read operation, the remaining rows of SOT-MRAM devices are unselected for read operation. For example, as shown in FIG. 3, during the third reading time period, the SOT-MRAM devices 300CA-300CD in the third row is selected for read operation, while the SOT-MRAM devices 300AA-300AD, the SOT-MRAM devices 300BA-300BD, and the SOT-MRAM devices 300DA-300DD are all unselected for read operation. During the third reading time period, a word read voltage V^{R}ₒₙ is applied to the read word line 140C, which drives the two-terminal read selector S2 in each of the SOT-MRAM devices 300CA-300CD into the conducting state. Also, during the third reading time period, a word unselect voltage V^{R}_{off} is applied to each of the read word lines 140A-140B and 140D, which drives the two-terminal read selector S2 in each of the SOT-MRAM devices 300AA-300AD, 300BA-300BD, and 300DA-300DD into the non-conducting state.

During the third reading time period, while the two-terminal read selector S2 in each of the SOT-MRAM devices 300CA-300CD is maintained at the conducting state, the current passing through the MTJ structure in each the SOT-MRAM devices 300CA-300CD flows correspondingly into one of the bit lines 190A-190D and accordingly charges each bit capacitor connected to the bit lines 190A-190D. The voltages V_{RB}[0], V_{RB}[1], V_{RB}[2], and V_{RB}[3] at the bit lines 190A-190D are correspondingly detected with sense amplifiers 398A-398D, and whereby the binary information stored in each of the SOT-MRAM devices 300CA-300CD is read out.

The write operation on a matrix of SOT-MRAM devices is described with reference to FIGS. 4A-4B. During the write operation, a read off voltage V_{read-off} is applied to each of the read word lines 140A-140D by the read selection circuit 340. The matrix of SOT-MRAM devices in FIGS. 4A-4B is written row by row. That is, during each writing time period, one row of SOT-MRAM devices is selected for write operation. The SOT-MRAM devices 300AA-300AD in the first row, the SOT-MRAM devices 300BA-300BD in the second row, the SOT-MRAM devices 300CA-300CD in the third row, and the SOT-MRAM devices 300DA-300DD in the fourth row are correspondingly written in a first writing time period, a second writing time period, a third writing time period, and a fourth writing time period.

During each writing time period, as one row of SOT-MRAM devices is selected for write operation, the remaining rows of SOT-MRAM devices are unselected for write operation. For example, as shown in FIGS. 4A-4B, during the second writing time period, the SOT-MRAM devices 300BA-300BD in the second row is selected for write operation, while the SOT-MRAM devices 300AA-300AD, the SOT-MRAM devices 300CA-300CD, and the SOT-MRAM devices 300DA-300DD are all unselected for write operation. In addition, each of the first writing time period, the second writing time period, the third writing time period, and the fourth writing time period is further divided into a positive-current writing time period and a negative-current writing time period.

As examples, the write operation during the second writing time period is described with reference to FIGS. 4A-4B. The write operation during the positive-current writing time period of the second writing time period is described with reference to FIG. 4A. The write operation during the negative-current writing time period of the second writing time period is described with reference to FIG. 4B.

During the positive-current writing time period of the second writing time period, as shown in FIG. 4A, a positive selecting voltage |V⁺ₒₙ| is applied to the write word line 130B, and a word unselect voltage V_{off} is applied to each of the write word lines 130A and 130C-130D. The word unselect voltage V_{off} drives the two-terminal write selector S1 in each of the SOT-MRAM devices 300AA-300AD, 300CA-300CD, and 300DA-300DD into the non-conducting state. Whether the two-terminal write selector S1 in a particular SOT-MRAM device in the second row (i.e., one of the SOT-MRAM devices 300BA-300BD) is driven into the conducting state depends upon the bit voltage V_{B}[i] on the bit line connected to the particular SOT-MRAM device. Here, the bit voltage V_{B}[i] is used to identify V_{B}[0], V_{B}[1], V_{B}[2], or V_{B}[3]. If the bit voltage V_{B}[i] on the bit line is the negative voltage −|V⁻|, a first binary value (such as the value “1”) is written into the particular SOT-MRAM device, as the two-terminal write selector S1 in the particular SOT-MRAM device is driven into the conducting state. On the other hand, if the bit voltage V_{B}[i] on the bit line is the positive voltage |V⁺| or the null voltage |V⁰|, the stored bit value in the particular SOT-MRAM device is unchanged, as the two-terminal write selector S1 in the particular SOT-MRAM device remains at the non-conducting state.

During the negative-current writing time period of the second writing time period, as shown in FIG. 4B, a negative selecting voltage −|V⁻ₒₙ| is applied to the write word line 130B, and a word unselect voltage V_{off} is applied to each of the write word lines 130A and 130C-130D. The word unselect voltage V_{off} drives the two-terminal write selector S1 in each of the SOT-MRAM devices 300AA-300AD, 300CA-300CD, and 300DA-300DD into the non-conducting state. Whether the two-terminal write selector S1 in a particular SOT-MRAM device in the second row (i.e., one of the SOT-MRAM devices 300BA-300BD) is driven into the conducting state depends upon the bit voltage V_{B}[i] on the bit line connected to the particular SOT-MRAM device. Here, the bit voltage V_{B}[i] is used to identify V_{B}[0], V_{B}[1], V_{B}[2], or V_{B}[3]. If the bit voltage V_{B}[i] on the bit line is the negative voltage −|V⁻| or the null voltage |V⁰|, the stored bit value in the particular SOT-MRAM device is unchanged, as the two-terminal write selector S1 in the particular SOT-MRAM device remains at the non-conducting state. On the other hand, if the bit voltage V_{B}[i] on the bit line is the positive voltage |V⁺|, a second binary value (such as the value “0”) is written into the particular SOT-MRAM device, as the two-terminal write selector S1 in the particular SOT-MRAM device is driven into the conducting state.

In one example, assume the bit pattern of the word stored in the second row (i.e., in the SOT-MRAM devices 300BA-300BD) before the write operation on the second row is of the form “xxxx”, where each of the bit “x” represents either the value “1” or the value “0” already stored in a SOT-MRAM device. In an example implementation, the bit voltages V_{B}[0], V_{B}[1], V_{B}[2], and V_{B}[3] on the bit lines 190A-190D are correspondingly set to the values |V⁺|, −|V⁻|, −|V⁻|, and |V⁺|. After the write operation is performed on the second row (i.e., after both the positive-current writing time period and the negative-current writing time period), a bit pattern of the form “0110” is stored in the second row (i.e., in the SOT-MRAM devices 300BA-300BD). In some example designs of various voltage values, |V⁻|=|V⁺|=(1/2)|V⁺ₒₙ|=(1/2)|V⁻ₒₙ|.

In another example implementation, the bit voltages V_{B}[0], V_{B}[1], V_{B}[2], and V_{B}[3] on the bit lines 190A-190D are correspondingly set to the values |V⁰|, −|V⁻|, −|V⁻|, and |V⁰| during the positive-current writing time period, but the bit voltages V_{B}[0], V_{B}[1], V_{B}[2], and V_{B}[3] on the bit lines 190A-190D are correspondingly set to the values |V⁺|, |V⁰|, |V⁰|, and |V⁺| during the negative-current writing time period. Then, after the write operation is performed on the second row, a bit pattern of the form “0110” is stored in the second row (i.e., in the SOT-MRAM devices 300BA-300BD). In some example designs of various voltage values, |V⁻|=|V⁺|=|V⁺ₒₙ|=|V⁻ₒₙ|, and |V⁰|=0.

In some embodiments, the write operation for writing the first binary value (such as the value “1”) as shown in FIG. 4A is performed before the write operation for writing the second binary value (such as the value “0”) as shown in FIG. 4B. During the positive-current writing time period, the bit pattern of the word stored in the second row (i.e., in the SOT-MRAM devices 300BA-300BD) changes from the form of “xxxx” to the form of “x11x”. During the negative-current writing time period, the bit pattern of the word stored in the second row (i.e., in the SOT-MRAM devices 300BA-300BD) changes from the form of “x11x” to the form of “0110”.

In some embodiments, the write operation for writing the second binary value (such as the value “0”) as shown in FIG. 4B is performed before the write operation for writing the first binary value (such as the value “1”) as shown in FIG. 4A. During the negative-current writing time period, the bit pattern of the word stored in the second row (i.e., in the SOT-MRAM devices 300BA-300BD) changes from the form of “xxxx” to the form of “0xx0”. During the positive-current writing time period, the bit pattern of the word stored in the second row (i.e., in the SOT-MRAM devices 300BA-300BD) changes from the form of “0xx0” to the form of “0110”.

In some embodiments, the two-terminal write selector S1 in each SOT-MRAM device has a symmetric current-voltage curve with respect to a forward bias voltage and a backward bias voltage, and each of the forward bias threshold voltage and the backward bias threshold voltage is characterized by a same threshold voltage |Vₜₕ|. Each of the positive selecting voltage |V⁺ₒₙ| and the negative selecting voltage |V⁻ₒₙ| applied to write word lines is selected to be α|Vₜₕ|. Each of the absolute voltage values |V⁻| and |V⁺| is selected to be β|Vₜₕ|.

In a first example implementation, each bit voltage V_{B}[i] on the bit line is set to one of two voltage values: a negative voltage β|Vₜₕ| for writing the first binary value (such as the value “1”) into a corresponding SOT-MRAM device, and a positive voltage β|Vₜₕ| for writing the second binary value (such as the value “0”) into a corresponding SOT-MRAM device. During both the positive-current writing time period and the negative-current writing time period, the negative voltage −β|Vₜₕ| is applied to each bit line for writing the binary value “1”, and the positive voltage β|Vₜₕ| is applied to each bit line for writing the binary value “0”. In some of the example designs, β=α/2, and 2/3<α<2.

In a second example implementation, each bit voltage V_{B}[i] on the bit line is set to one of three voltage values: a negative voltage −β|Vₜₕ| for writing the first binary value (such as the value “1”) into a corresponding SOT-MRAM device, a positive voltage β|Vₜₕ| for writing the second binary value (such as the value “0”) into a corresponding SOT-MRAM device, and a null voltage |V⁰| for maintaining the binary value of a corresponding SOT-MRAM device. During the positive-current writing time period, the negative voltage −β|Vₜₕ| is applied to each bit line for writing the binary value “1”, and the null voltage |V⁰|=0 is applied to the remaining bit lines. During the negative-current writing time period, the positive voltage β|Vₜₕ| is applied to each bit line for writing the binary value “0”, and the null voltage |V⁰|=0 is applied to the remaining bit lines. In some of the example designs, β=a, and 1/2<α<1.

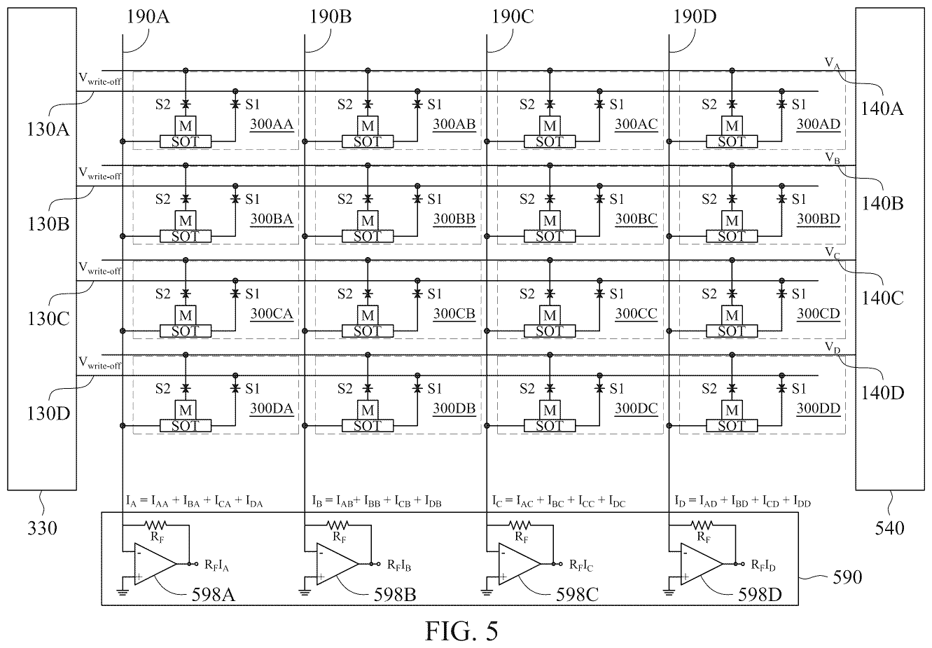

FIG. 5 is a circuit diagram of an integrated circuit having a matrix of SOT-MRAM devices configured to perform a matrix operation on a vector, in accordance with some embodiments. In FIG. 5, each of the write word lines 130A-130D is connected to the write selection circuit 330. The write selection circuit 330 in FIG. 5 and the write selection circuit 330 in FIG. 3 and FIGS. 4A-4B perform the same functions. In FIG. 5, each of the read word line 140A-140D is connected to a vector input circuit 540 (which is modified from the read selection circuit 340 in FIG. 3 and FIGS. 4A-4B). In FIG. 5, each of the bit lines 190A-190D is connected to a memory input-output circuit 590 (which is modified from the memory input-output circuit 390 in FIG. 3 and FIGS. 4A-4B).

In the matrix operation on a vector, the input vector is represented by an array of voltages V_{A}, V_{B}, V_{C}, and V_{D} generated by the vector input circuit 540. The voltages V_{A}, V_{B}, V_{C}, and V_{D} are correspondingly applied to the read word lines 140A, 140B, 140C, and 140D. In response to the voltages applied to the read word lines, currents I_{A}, I_{B}, I_{C}, and I_{D} are correspondingly induced in the bit lines 190A, 190B, 190C, and 190D. The currents I_{A}, I_{B}, I_{C}, and I_{D} are correspondingly measured with current-to-voltage converters 598A, 598B, 598C, and 598D. In one example implementation, each of the current-to-voltage converters has a feedback resistor R_{F}, and the output voltages at the current-to-voltage converters 598A, 598B, 598C, and 598D correspondingly have the voltage values R_{F}I_{A}, R_{F}I_{B}, R_{F}I_{C}, and R_{F}I_{D}.

The current I_{A} in the bit line 190A is the sum of the currents I_{AA}, I_{BA}, I_{CA}, and I_{DA}, which are the currents following to the bit line 190A correspondingly from the read word lines 140A, 140B, 140C, and 140D. The current I_{B} in the bit line 190B is the sum of the currents I_{AB}, I_{BB}, I_{CB}, and I_{DB}, which are the currents following to the bit line 190B correspondingly from the read word lines 140A, 140B, 140C, and 140D. The current I_{C} in the bit line 190C is the sum of the currents I_{AC}, I_{BC}, I_{CC}, and I_{DC}, which are the currents following to the bit line 190C correspondingly from the read word lines 140A, 140B, 140C, and 140D. The current I_{D} in the bit line 190D is the sum of the currents I_{AD}, I_{BD}, I_{CD}, and I_{DD}, which are the currents following to the bit line 190D correspondingly from the read word lines 140A, 140B, 140C, and 140D.

Each of the currents I_{AA}, I_{BA}, I_{CA}, and I_{DA} is related to a corresponding conductance G_{AA}, G_{BA}, G_{CA}, and G_{DA} of the SOT-MRAM devices 300AA, 300BA, 300CA, and 300DA. Each of the currents I_{AB}, I_{BB}, I_{CB}, and I_{DB} is related to a corresponding conductance G_{AB}, G_{BB}, G_{CB}, and G_{DB} of the SOT-MRAM devices 300AB, 300BB, 300CB, and 300 DB. Each of the currents I_{AC}, I_{BC}, I_{CC}, and I_{DC} is related to a corresponding conductance G_{AC}, G_{BC}, G_{CC}, and G_{DC} of the SOT-MRAM devices 300AC, 300BC, 300CC, and 300DC. Each of the currents I_{AD}, I_{BD}, I_{CD}, and I_{DD} is related to a corresponding conductance G_{AD}, G_{BD}, G_{CD}, and G_{DD} of the SOT-MRAM devices 300AD, 300BD, 300CD, and 300DD.

In FIG. 5, because of the current-to-voltage converters 598A, 598B, 598C, and 598D, each of the bit lines 190A-190D is connected to the virtual ground.

Consequently, the currents I_{AA}, I_{BA}, I_{CA}, and I_{DA} are correspondingly equal to G_{AA}V_{A}, G_{BA}V_{B}, G_{CA} V_{C}, and G_{DA}V_{D}. The currents I_{AB}, I_{BB}, I_{CB}, and I_{DB} are correspondingly equal to G_{AB} V_{A}, G_{BB}V_{B}, G_{CB} V_{C}, and G_{DB} V_{D}. The currents I_{AC}, I_{BC}, I_{CC}, and I_{DC} are correspondingly equal to G_{AC}V_{A}, G_{BC}V_{B}, G_{CC}V_{C}, and G_{DC}V_{D}. The currents I_{AD}, I_{BD}, I_{CD}, and I_{DD} are correspondingly equal to G_{AD}V_{A}, G_{BD}V_{B}, G_{CD}V_{C}, and G_{DD}V_{D}. Therefore, the currents I_{A}, I_{B}, I_{C}, and I_{D} are correspondingly provided by the following equations:

$${I}_{A} = {G}_{AA} {V}_{A} + {G}_{BA} {V}_{B} + {G}_{CA} {V}_{C} + {G}_{DA} {V}_{D} , \\ {I}_{B} = {G}_{AB} {V}_{A} + {G}_{BB} {V}_{B} + {G}_{CB} {V}_{C} + {G}_{DB} {V}_{D} , \\ {I}_{C} = {G}_{AC} {V}_{A} + {G}_{BC} {V}_{B} + {G}_{CC} {V}_{C} + {G}_{DC} {V}_{D} , and \\ {I}_{D} = {G}_{AD} {V}_{A} + {G}_{BD} {V}_{B} + {G}_{CD} {V}_{C} + {G}_{DD} {V}_{D} .$$

Written in the form of linear algebra, an output vector (as represented by an array of the currents I_{A}, I_{B}, I_{C}, and I_{D}) is transformed from the input vector (as represented by an array of the voltages V_{A}, V_{B}, V_{C}, and V_{D}) by a conductance matrix [symbol] , as shown in the following equation:

$$( \begin{matrix}{I}_{A} \\ {I}_{B} \\ {I}_{C} \\ {I}_{D}\end{matrix} ) = ( \begin{matrix}{G}_{AA} & {G}_{BA} & {G}_{CA} & {G}_{DA} \\ {G}_{AB} & {G}_{BB} & {G}_{CB} & {G}_{DB} \\ {G}_{AC} & {G}_{BC} & {G}_{CC} & {G}_{DC} \\ {G}_{AD} & {G}_{BD} & {G}_{CD} & {G}_{DD}\end{matrix} ) ( \begin{matrix}{V}_{A} \\ {V}_{B} \\ {V}_{C} \\ {V}_{D}\end{matrix} ) .$$

Each element in the conductance matrix [symbol] is a conductance of a SOT-MRAM device (e.g., 100 or 200, in FIGS. 1A and 2A) as measured between the conductor layer 122 of the two-terminal read selector 120 and the second terminal of the SOT conductor 160. In some embodiments, as the on-resistance Ron of the two-terminal read selector 120 in the SOT-MRAM is reduced, the conductance of the SOT-MRAM device is dominated by the conductance of the MTJ structure 150. Because the conductance of the MTJ structure 150 in each SOT-MRAM device in the matrix of SOT-MRAM devices (as shown in FIGS. 4A-4B) is individually reprogrammable, the conductance matrix [symbol] for transforming the input vector (such as the array of voltages V_{A}, V_{B}, V_{C}, and V_{D}) to the output vector (such as the array of currents I_{A}, I_{B}, I_{C}, and I_{D}) is reprogrammable. Consequently, in FIG. 5, the integrated circuit having a matrix of SOT-MRAM devices is operable as a Computing in Memory (“CIM”) device to perform a reprogrammable matrix operation on a vector.

The conductance matrix [symbol] is a 4-by-4 matrix due to the configuration of the matrix of SOT-MRAM devices in FIG. 5, which are arranged in 4 rows and 4 columns. The matrix of SOT-MRAM devices in FIG. 5 is provided as an example, matrixes of other dimensions are within the contemplated scope of the present disclosure. For example, a CIM device having a matrix of SOT-MRAM devices arranged in 3 rows and 4 columns is operable to transform a 3-dimensional input vector (such as voltages V_{A}, V_{B}, and V_{C}) into a 4-dimensional output vector (such as currents I_{A}, I_{B}, I_{C}, and I_{D}). A CIM deice having a matrix of SOT-MRAM devices arranged in 4 rows and 3 columns is operable to transform a 4-dimensional input vector (such as voltages V_{A}, V_{B}, V_{C}, and V_{D}) into a 3-dimensional output vector (such as currents I_{A}, I_{B}, and I_{C}). In general, a CIM deice having a matrix of SOT-MRAM devices arranged in m rows and n columns is operable to transform a m-dimensional input vector into an n-dimensional output vector.

In some embodiments, the voltage of each element in the input vector (e.g., voltages V_{A}, V_{B}, V_{C}, or V_{D}) is a variable of analog value. In some embodiments, the voltage of each element in the input vector (e.g., voltages V_{A}, V_{B}, V_{C}, or V_{D}) is a variable of digital value represented by multiple bits. In some embodiments, the voltage of each element in the input vector (e.g., voltages V_{A}, V_{B}, V_{C}, or V_{D}) is a variable of single bit which takes one of two binary values. In one example, the voltage of each element in the input vector takes one of the two binary values which are either V_{R,OFF}=0 or V_{R,ON}>V_{TH}, where V_{TH} is the selector threshold voltage.

In FIG. 5, each element in the conductance matrix [symbol] is determined based on a conductance of a SOT-MRAM device having one MTJ structure (i.e., 150), because the single SOT-MRAM device having one MTJ structure is the memory element connected between a bit line and each of a write word line and a read word line. In some alternative embodiments, with the configuration that the memory element connected between a bit line and each of a write word line and a read word line includes multiple SOT-MRAM devices each having one MTJ structure, an element in the conductance matrix G is determined based on the combination of the conductance of multiple SOT-MRAM devices. With the alternative embodiments, an element in the conductance matrix G is a multiple bit variable, even if a single SOT-MRAM device having one MTJ structure is implemented to have a conductance with binary values of a single bit.

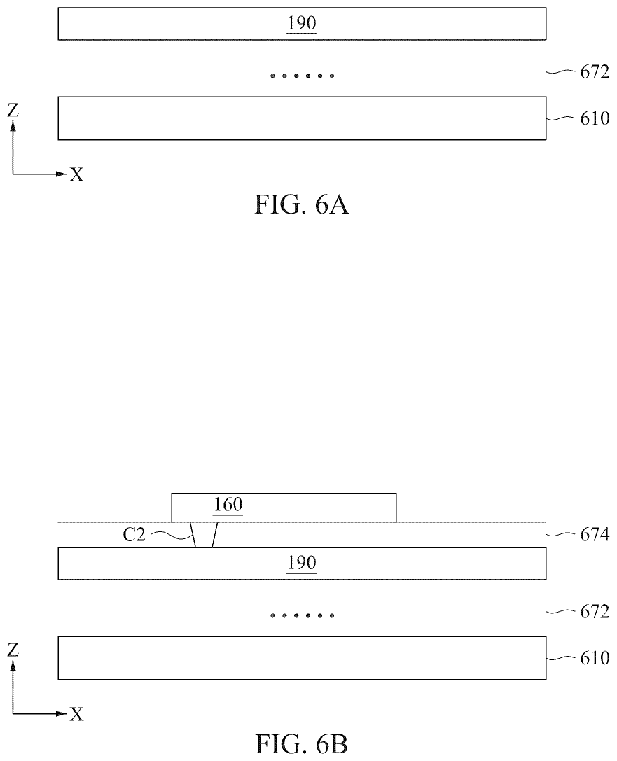

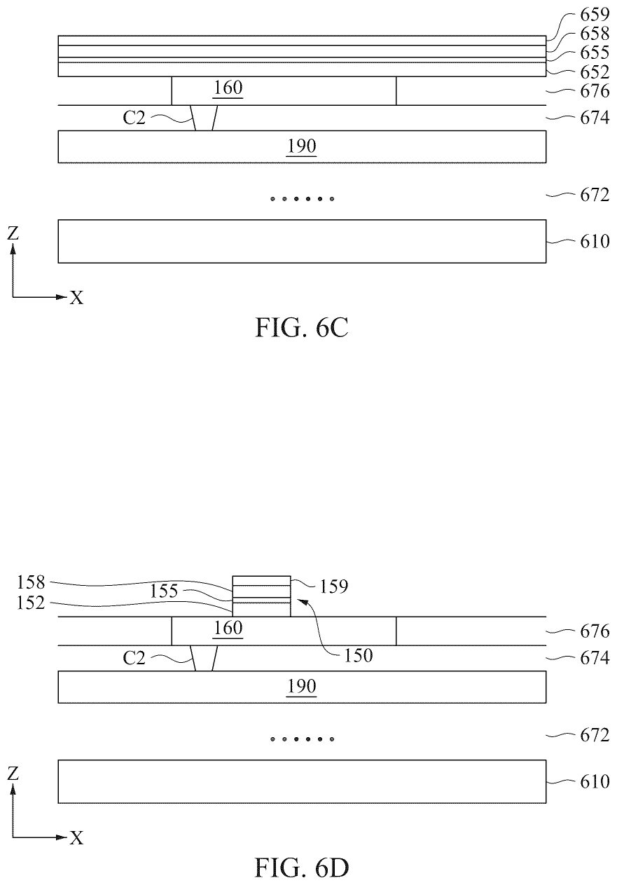

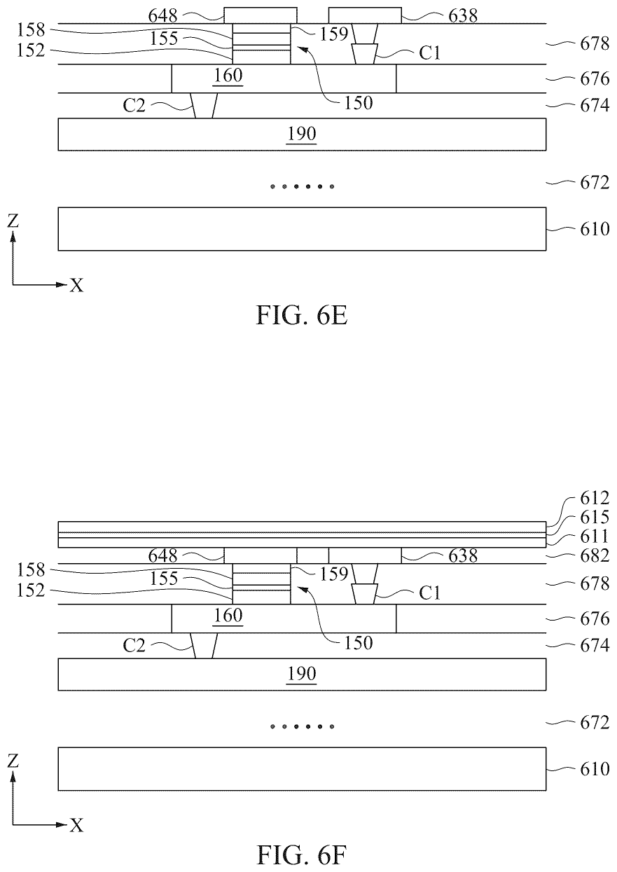

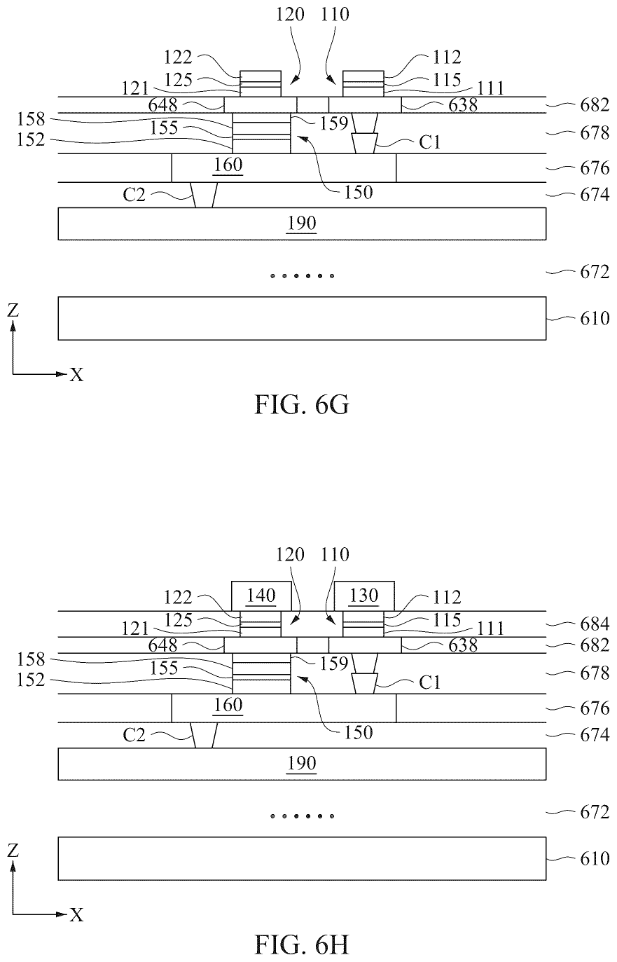

FIGS. 6A-6H are cross-sectional views of various device structures formed during a process of fabricating the SOT-MRAM device of FIG. 2A, in accordance with some embodiments. After fabricating a device structure 610 with the front-end-of-line (FEOL) process in which individual components such as transistors, capacitors, and resistors are formed on a substrate, in a step during the back end of line (BEOL) process, as shown in FIG. 6A, the bit line 190 extending in the X-direction is fabricated overlying a layer of insulating material 672 atop the device structure 610. Various layers of other materials or elements between the device structure 610 and the layer of insulating material 672 are not explicitly shown in the figure.

In the next step, as shown in FIG. 6B, the SOT conductor 160 extending in the X-direction is fabricated overlying a layer of insulating material 674 atop the bit line 190. In addition, the vertical conductor C2 connecting the SOT conductor 160 and the bit line 190 is formed with a via-connector that passes through the layer of insulating material 674. In some embodiments, the SOT conductor 160 is made of one or more heavy metals or materials doped by heavy metals. Examples of the materials used in the SOT conductor 160 include Pt, W, Ta, AuPt, W3Ta, BixSey, BiSeTe, or combinations of.

In the next step, as shown in FIG. 6C, a stack of multiple layers of various materials is fabricated covering the SOT conductor 160 and the layer of insulating material 676 atop the layer of insulating material 674. The stack of multiple layers includes two layers of ferromagnetic material 652 and 658, a thin insulating layer 655, and a layer of Synthetic Anti-Ferromagnetic (“SAF”) material 659. The layer of ferromagnetic material 652 is deposited overlying the SOT conductor 160 and the layer of insulating material 676. The thin insulating layer 655 is deposited overlying the layer of ferromagnetic material 652. The layer of ferromagnetic material 658 is deposited overlying the thin insulating layer 655. The layer of Synthetic Anti-Ferromagnetic material 659 is deposited overlying the layer of ferromagnetic material 658. In some embodiments, the layer of Synthetic Anti-Ferromagnetic material 659 includes a stack of ferromagnetic layers separated by one or more non-magnetic layers. In some embodiments, the layer of Synthetic Anti-Ferromagnetic material 659 includes a stack of alternating non-magnetic layers and ferromagnetic layers, in which each of the non-magnetic layers is sandwiched between two ferromagnetic layers.

In the next step, as shown in FIG. 6D, after the stack of multiple layers in FIG. 6C is covered with a mask having patterns formed with photolithography techniques, the multiple layers of various materials (labeled as 652, 655, 658, and 659) are etched with dry etching techniques, whereby the MTJ structure 150 is fabricated atop the SOT conductor 160. The layer of Synthetic Anti-Ferromagnetic material 659, the layer of ferromagnetic material 658, the thin insulating layer 655, and the layer of ferromagnetic material 652 are etched sequentially. The MTJ structure 150 fabricated in FIG. 6D includes a SAF layer 159 which is in contact with the pinned layer 158. The exchange coupling between the SAF layer 159 and the pinned layer 158 causes the magnetic moments of the pinned layer 158 to align in a preferred direction. The SAF layer 159 of the MTJ structure 150 is formed by etching the layer of Synthetic Anti-Ferromagnetic material 659. The pinned layer 158 of the MTJ structure 150 is formed by etching the layer of ferromagnetic material 658. The tunnel barrier layer 155 of the MTJ structure 150 is formed by etching the thin insulating layer 655. The free layer 152 of the MTJ structure 150 is formed by etching the layer of ferromagnetic material 652.

In the next step, as shown in FIG. 6E, a conductive segment 648 atop the SAF layer 159 and a conductive segment 638 overlying an interlayer dielectric 678 (“ILD”) are fabricated. The conductive segment 648 is in conductive contact with the SAF layer 159. Because the SAF layer 159 is also conductive, the conductive segment 648 becomes a terminal of the MTJ structure 150. The conductive segment 638 is conductively connected to the first terminal of the SOT conductor 160 through the vertical conductor C1 which is formed through one or more via-connectors passing through the interlayer dielectric 678.

In the next step, as shown in FIG. 6F, a stack of multiple layers of various materials is fabricated covering the conductive segments 638 and 648 and covering an ILD 682 atop the interlayer dielectric 678. The stack of multiple layers includes a layer of conductive material 611, a layer of switching material 615, and a layer of conductive material 612. The layer of conductive material 611 is deposited overlying the conductive segments 638 and 648 and the ILD 682. The switching material 615 is deposited overlying the layer of conductive material 611. The layer of conductive material 612 is deposited overlying the layer of switching material 615. Examples of the switching material include a chalcogenide material, a solid-electrolyte material, a phase-change material, or an oxide insulating material.

In some embodiments, the switching material 615 is made of HfOx (where 0<x≤2) which is doped with one or more materials, such as Cu, Al, N, P, S, Si, Zr, Gd, Ti, La, or Te. In some embodiments, the switching material 615 is made of GeSe doped with one or more elements selected from the group consisting of N, P, S, Si, and Te. In some embodiments, the switching material 615 is made of AsGeSe doped with one or more elements selected from the group consisting of N, P, S, Si, and Te. In some embodiments, the switching material 615 is made of AsGeSeSi doped with one or more elements selected from the group consisting of N, P, S, Si, and Te. In some embodiments, the switching material 615 includes GeCTe, NGeCTe, SiNGeCTe, or a combination thereof. In some embodiments, the switching material 615 is made of a chalcogenide or a solid-electrolyte material containing one or more of Ge, Sb, S, and Te. In some embodiments, the switching material 615 is made of a material including SiOₓ, TiOₓ, AlOₓ, WOₓ, TiₓN_{y}O_{z}, TaOₓ, Nbₓ, or a combination thereof, where x, y and z are non-stoichiometric values. In some embodiments, the switching material 615 is made of an oxygen deficient transition metal oxide or an ovonic threshold switching (OTS) material.

In the next step, as shown in FIG. 6G, after the stack of multiple layers in FIG. 6F is covered with a mask having patterns formed with photolithography techniques, the multiple layers of various materials (labeled as 611, 615, and 612) are etched with dry etching techniques, whereby the two-terminal write selector 110 is fabricated atop the conductive segment 638 and the two-terminal read selector 120 is fabricated atop the conductive segment 648. The layer of conductive material 612, the layer of switching material 615, and the layer of conductive material 611 are etched sequentially. Each of the conductive segments 638 and 648 functions as an etching stopper during the etching process. The conductor layer 112 of the two-terminal write selector 110 and the conductor layer 122 of the two-terminal read selector 120 are formed by etching the layer of conductive material 612. The switching layer 115 of the two-terminal write selector 110 and the switching layer 125 of the two-terminal read selector 120 are formed by etching the layer of switching material 615. The conductor layer 111 of the two-terminal write selector 110 and the conductor layer 121 of the two-terminal read selector 120 are formed by etching the layer of conductive material 611.

In the next step, as shown in FIG. 6H, the write word line 130 is fabricated atop the conductor layer 112 of the two-terminal write selector 110, and the read word line 140 is fabricated atop the conductor layer 122 of the two-terminal read selector 120. The write word line 130 and the read word line 140 are fabricated in a same conductive layer atop an ILD 684 which covers the conductive segments 638 and 648 and the ILD 682. Each of the write word line 130 and the read word line 140 extends in the Y-direction.

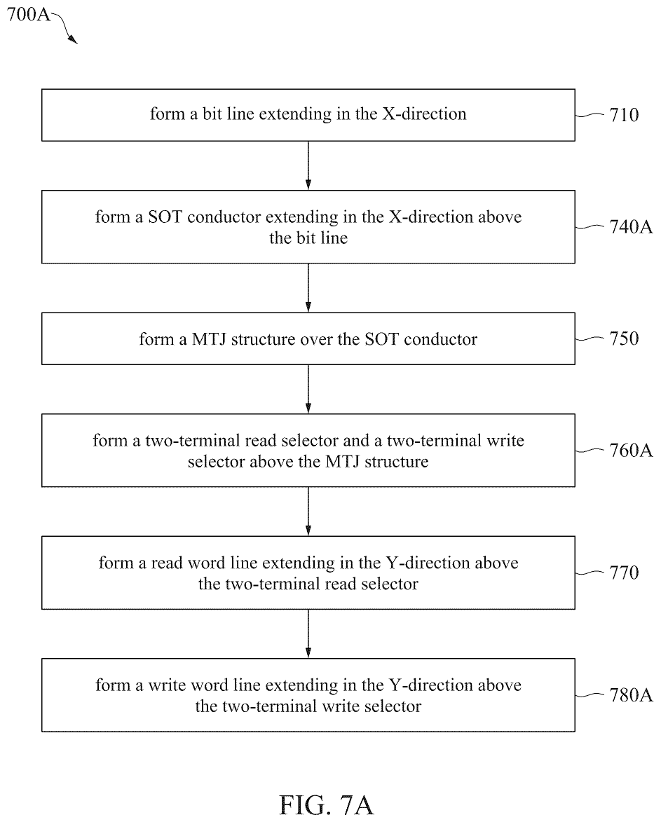

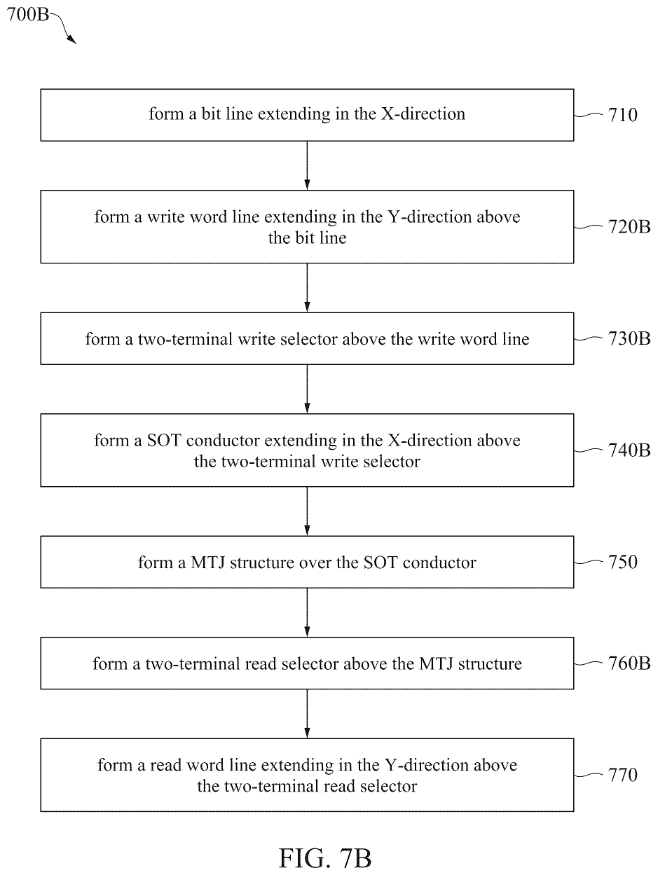

FIG. 7A is a flowchart of a method 700A of fabricating a memory device, in accordance with some embodiments. The sequence in which the operations of method 700A are depicted in FIG. 7A is for illustration only; the operations of method 700A are capable of being executed in sequences that differ from that depicted in FIG. 7A. It is understood that additional operations may be performed before, during, and/or after the method 700A depicted in FIG. 7A, and that some other processes may only be briefly described herein.

In operation 710 of method 700A, a bit line extending in the X-direction is formed above a device structure fabricated in a FEOL process. In the example as shown in FIG. 6A, the bit line 190 extending in the X-direction is fabricated overlying a layer of insulating material 672 atop the device structure 610 which is fabricated in a FEOL process.

In operation 740A of method 700A, a SOT conductor extending in the X-direction is formed above the bit line. In the example as shown in FIG. 6B, the SOT conductor 160 extending in the X-direction is fabricated overlying a layer of insulating material 674 atop the bit line 190.

In operation 750 of method 700A, a MTJ structure is formed over the SOT conductor. In the example as shown in FIGS. 6C-6D, the MTJ structure 150 is fabricated atop the SOT conductor 160.

In operation 760A of method 700A, a two-terminal read selector and a two-terminal write selector are formed above the MTJ structure. In the example as shown in FIGS. 6F-6G, the two-terminal write selector 110 is fabricated atop the conductive segment 638 and the two-terminal read selector 120 is fabricated atop the conductive segment 648. The conductive segments 638 and 648 are in a conductive layer above the MTJ structure 150.

In operation 770 of method 700A, a read word line extending in the Y-direction is formed above the two-terminal read selector. In the example as shown in FIG. 6H, the read word line 140 extending in the Y-direction is fabricated atop the conductor layer 122 of the two-terminal read selector 120.

In operation 780A of method 700A, a write word line extending in the Y-direction is formed above the two-terminal write selector. In the example as shown in FIG. 6H, the write word line 130 extending in the Y-direction is fabricated atop the conductor layer 112 of the two-terminal write selector 110.

Additionally, in the example as shown in FIG. 6H, the write word line 130 fabricated in operation 780A and the read word line 140 fabricated in operation 770 are fabricated in a same conductive layer atop an ILD 684.

FIG. 7B is a flowchart of a method 700B of fabricating a memory device, in accordance with some embodiments. The sequence in which the operations of method 700B are depicted in FIG. 7B is for illustration only; the operations of method 700B are capable of being executed in sequences that differ from that depicted in FIG. 7B. It is understood that additional operations may be performed before, during, and/or after the method 700B depicted in FIG. 7B, and that some other processes may only be briefly described herein.

In operation 710 of method 700B, a bit line extending in the X-direction is formed above a device structure fabricated in a FEOL process. For example, as the SOT-MRAM device 100 of FIG. 1A is fabricated with method 700B, the bit line 190 extending in the X-direction is fabricated above a device structure (not shown explicitly) which is formed in a FEOL process.

In operation 720B of method 700B, a write word line extending in the Y-direction is formed above the bit line. For example, as the SOT-MRAM device 100 of FIG. 1A is fabricated with method 700B, the write word line 130 is formed in a conductive layer above the bit line 190.

In operation 730B of method 700B, a two-terminal write selector is formed above the write word line. For example, as the SOT-MRAM device 100 of FIG. 1A is fabricated with method 700B, the two-terminal write selector 110 is formed above the write word line 130.

In operation 740B of method 700B, a SOT conductor extending in the X-direction is formed above the two-terminal write selector. For example, as the SOT-MRAM device 100 of FIG. 1A is fabricated with method 700B, the SOT conductor 160 extending in the X-direction is fabricated above the two-terminal write selector 110.

In operation 750 of method 700B, a MTJ structure is formed over the SOT conductor. For example, as the SOT-MRAM device 100 of FIG. 1A is fabricated with method 700B, the MTJ structure 150 is fabricated atop the SOT conductor 160.

In operation 760B of method 700B, a two-terminal read selector is formed above the MTJ structure. For example, as the SOT-MRAM device 100 of FIG. 1A is fabricated with method 700B, the two-terminal read selector 120 is fabricated above the MTJ structure 150.

In operation 770 of method 700B, a read word line extending in the Y-direction is formed above the two-terminal read selector. For example, as the SOT-MRAM device 100 of FIG. 1A is fabricated with method 700B, the read word line 140 extending in the Y-direction is fabricated atop the conductor layer 122 of the two-terminal read selector 120.

An aspect of the present disclosure relates to a memory device. The memory device includes a spin-orbit torque (“SOT”) conductor, and a magnetic tunneling junction (“MTJ”) structure arranged above the SOT conductor. The MTJ structure has a free layer, a pinned layer, and a tunnel barrier layer sandwiched between the free layer and the pinned layer. The free layer is in conductive contact with the SOT conductor. The memory device also includes a two-terminal read selector and a two-terminal write selector. The two-terminal read selector is conductively connected to the pinned layer in the MTJ structure, and the two-terminal read selector is arranged above the MTJ structure. The two-terminal write selector is conductively connected to a first terminal of the SOT conductor, and the two-terminal write selector is arranged above the MTJ structure. The memory device further includes a bit line conductively connected to a second terminal of the SOT conductor. The bit line is arranged below the SOT conductor.

Another aspect of the present disclosure relates to a memory device. The memory device includes a spin-orbit torque (“SOT”) conductor, and a magnetic tunneling junction (“MTJ”) structure arranged above the SOT conductor. The MTJ structure has a free layer, a pinned layer, and a tunnel barrier layer sandwiched between the free layer and the pinned layer, and wherein the free layer is in conductive contact with the SOT conductor. The memory device also includes a two-terminal read selector and a two-terminal write selector. The two-terminal read selector is conductively connected to the pinned layer in the MTJ structure, and the two-terminal read selector is arranged above the MTJ structure. The two-terminal write selector is conductively connected to a first terminal of the SOT conductor, and the two-terminal write selector is arranged below the MTJ structure. The memory device further includes a write word line and a bit line. The write word line is conductively connected to the two-terminal write selector, and the two-terminal write selector is arranged below the two-terminal write selector. The bit line is conductively connected to a second terminal of the SOT conductor, and the bit line is arranged below the write word line.

Still another aspect of the present disclosure relates to a method. The method includes forming a spin-orbit torque (“SOT”) conductor extending in a first direction, and forming a magnetic tunneling junction (“MTJ”) structure over the SOT conductor. In the method, forming the MTJ structure comprises depositing a free layer over the SOT conductor, depositing a tunnel barrier layer over the free layer, and depositing a pinned layer over the tunnel barrier layer. The method also includes forming a two-terminal read selector above the MTJ structure, and forming a two-terminal write selector. The two-terminal read selector is conductively connected to the pinned layer in the MTJ structure. The two-terminal write selector is conductively connected to a first terminal of the SOT conductor.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A memory device comprising:
a spin-orbit torque (“SOT”) conductor;
a magnetic tunneling junction (“MTJ”) structure arranged above the SOT conductor, wherein the MTJ structure has a free layer, a pinned layer, and a tunnel barrier layer sandwiched between the free layer and the pinned layer, and wherein the free layer is in conductive contact with the SOT conductor;
a two-terminal read selector conductively connected to the pinned layer in the MTJ structure, wherein the two-terminal read selector is arranged above the MTJ structure;
a two-terminal write selector conductively connected to a first terminal of the SOT conductor, wherein the two-terminal write selector is arranged above the MTJ structure; and
a bit line conductively connected to a second terminal of the SOT conductor, wherein the bit line is arranged below the SOT conductor.

2. The memory device of claim 1, further comprising:
a read word line conductively connected to the two-terminal read selector, wherein the read word line is arranged above the two-terminal read selector.

3. The memory device of claim 1, further comprising:
a write word line conductively connected to the two-terminal write selector, wherein the write word line is arranged above the two-terminal write selector.

4. The memory device of claim 1, further comprising:
a read word line conductively connected to the two-terminal read selector; and
a write word line conductively connected to the two-terminal write selector.

5. The memory device of claim 4, wherein the read word line and the write word line are in a same conductive layer above the two-terminal write selector.

6. The memory device of claim 4, wherein each of the SOT conductor and the bit line extends in a first direction, and wherein the write word line and the read word line extend in a second direction that is perpendicular to the first direction.

7. The memory device of claim 1, wherein each of the two-terminal read selector and the two-terminal write selector is a non-linear diode.

8. The memory device of claim 1, wherein each of the two-terminal read selector and the two-terminal write selector includes a switching layer sandwiched between a first conductor layer and a second conductor layer.

9. The memory device of claim 8, wherein the switching layer in the two-terminal read selector and the switching layer in the two-terminal write selector are formed from a same layer of switching material.

10. The memory device of claim 8, wherein at least the switching layer in the two-terminal write selector includes a phase-change material.

11. The memory device of claim 8, wherein at least the switching layer in the two-terminal write selector includes a chalcogenide material or a solid-electrolyte material.

12. A memory device comprising:
a spin-orbit torque (“SOT”) conductor;
a magnetic tunneling junction (“MTJ”) structure arranged above the SOT conductor, wherein the MTJ structure has a free layer, a pinned layer, and a tunnel barrier layer sandwiched between the free layer and the pinned layer, and wherein the free layer is in conductive contact with the SOT conductor;
a two-terminal read selector conductively connected to the pinned layer in the MTJ structure, wherein the two-terminal read selector is arranged above the MTJ structure;
a two-terminal write selector conductively connected to a first terminal of the SOT conductor, wherein the two-terminal write selector is arranged below the MTJ structure;
a write word line conductively connected to the two-terminal write selector, wherein the write word line is arranged below the two-terminal write selector; and
a bit line conductively connected to a second terminal of the SOT conductor, wherein the bit line is arranged below the write word line.

13. The memory device of claim 12, further comprising:
a read word line conductively connected to the two-terminal read selector, wherein the read word line is arranged above the two-terminal read selector.

14. The memory device of claim 13, wherein the SOT conductor extends in a first direction, and wherein the write word line and the read word line extend in a second direction that is perpendicular to the first direction.

15. The memory device of claim 14, wherein the bit line extends in the first direction and is vertically stacked with the SOT conductor.

16. A method comprising:
forming a spin-orbit torque (“SOT”) conductor extending in a first direction;
forming a magnetic tunneling junction (“MTJ”) structure over the SOT conductor, wherein forming the MTJ structure comprises depositing a free layer over the SOT conductor, depositing a tunnel barrier layer over the free layer, and depositing a pinned layer over the tunnel barrier layer; and
forming a two-terminal read selector above the MTJ structure, wherein the two-terminal read selector is conductively connected to the pinned layer in the MTJ structure; and
forming a two-terminal write selector which is conductively connected to a first terminal of the SOT conductor.

17. The method of claim 16, further comprising:
forming a read word line extending in a second direction above the two-terminal read selector, wherein the second direction is perpendicular to the first direction.

18. The method of claim 16, further comprising:
forming the two-terminal write selector above the MTJ structure; and
forming a write word line extending in a second direction above the two-terminal write selector.

19. The method of claim 16, wherein forming the SOT conductor comprise forming the SOT conductor above the two-terminal write selector, and wherein the two-terminal write selector is formed after forming a write word line extending in a second direction.

20. The method of claim 16, further comprising:
forming a bit line extending in the first direction; and
forming the SOT conductor above the bit line and having a second terminal conductively connected to the bit line, wherein the SOT conductor is vertically stacked with the bit line.
